(19) United States
(12) Patent Application Publication
(10) Pub. No.: US 2021/0098549 A1
(43) Pub. Date: Apr. 1, 2021

(54) THIN FILM TRANSISTOR ARRAY SUBSTRATE AND ORGANIC LIGHT EMITTING DIODE PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: FENG ZHANG, Wuhan, Hubei (CN); Chao DAI, Wuhan, Hubei (CN)

(21) Appl. No.: 16/644,218

(22) PCT Filed: Feb. 18, 2020
(86) PCT No.: PCT/CN2020/075623

§ 371 Date: Mar. 4, 2020

(30) Foreign Application Priority Data
Aug. 22, 2019 (CN) 201910776539.9

(51) Int. Cl. H01L 27/32; H01L 51/00; H01L 27/12; H01L 51/52

(52) U.S. Cl. CPC H01L 27/3262; H01L 51/0097; H01L 27/3246; H01L 51/5253; H01L 27/1225

(57) ABSTRACT

A thin film transistor (TFT) array substrate and an organic light emitting diode (OLED) panel are provided. The TFT array substrate includes an display area, and the TFT array substrate includes: a substrate; a driving thin film transistor disposed on the substrate and located in a display area, wherein the driving thin film transistor includes a polysilicon semiconductor layer; and a switching thin film transistor disposed on the substrate, located in the display area, and electrically connected to the driving thin film transistor, wherein the switching thin film transistor includes an oxide semiconductor layer.

### FIELD OF INVENTION

The present disclosure relates to the field of display technologies, and more particularly, to a thin film transistor (TFT) array substrate and an organic light emitting diode (OLED) panel.

### BACKGROUND OF INVENTION

Organic light emitting diodes (OLEDs) have many excellent features, such as wide viewing angles, wide color gamuts, high contrast, low power consumption, and foldability/flexibility. OLEDs have strong competitiveness in the new generation display technology, wherein active-matrix organic light-emitting diode (AMOLED) technology is one of the key development directions of the current display technology.

### Technical Problems

The basic pixel driving circuit of AMOLED includes at least one switching thin film transistor (STFT), one driving thin film transistor (DTFT), and one storage capacitor Cst. Because DTFT is restricted by the uniformity of the process and the attenuation with use time, the threshold voltage (Vth) of the DTFT is easy to drift. As a result, the OLED driving current is prone to change, which makes the OLED display image uneven and affects the image quality. Therefore, pixel circuits with compensation functions are used in actual panels to achieve desired image quality, such as the 6 transistors and 1 storage capacitor (6T1C) pixel compensation circuit as shown in FIG. 1. However, the TFTs made by low-temperature polysilicon (LTPS) technology usually have large leakage current, which makes the data voltage across the storage capacitor difficult to be maintained. The abnormalities, such as unstable brightness or broken bright spots on the OLED panel display, may occur. Therefore, in actual circuit design, the STFT_T3 and T4 as shown in FIG. 1 are usually designed as a double gate structure to suppress the influence of the leakage current on the pixel circuit. However, such a design may affect the flexibility of AMOLED displays.

Therefore, it is necessary to provide a thin film transistor (TFT) array substrate and an organic light emitting diode (OLED) panel to solve the problems of the prior art.

### SUMMARY OF INVENTION

### Technical Solutions

The object of the present disclosure is to provide a thin film transistor (TFT) array substrate and an organic light emitting diode (OLED) panel. The TFTs formed by oxide semiconductor are used to replace the STFT formed by LTPS to reduce the occurrence of pixel circuit leakage current, thereby improving the display quality of the OLED panel. Moreover, the TFT formed by oxide semiconductor has excellent bendability.

In order to achieve the aforementioned object of the present disclosure, the present disclosure provides an organic light emitting diode (OLED) panel, including:

a thin film transistor (TFT) array substrate including a display area and a bendable area, the TFT array substrate including a flexible substrate; a driving thin film transistor disposed on the flexible substrate and located in the display area, wherein the driving thin film transistor includes a polysilicon semiconductor layer; a switching thin film transistor disposed on the flexible substrate, located in the display area, and electrically connected to the driving thin film transistor, wherein the switching thin film transistor includes an oxide semiconductor layer; and an organic filling layer disposed on the flexible substrate and located in the bendable area;

a planarization layer disposed on the TFT array substrate; and

an organic light emitting device layer disposed on the planarization layer, the organic light emitting device layer including an organic light emitting diode (OLED) located in the display area, and the OLED electrically connected with the driving thin film transistor;

wherein the oxide semiconductor layer is an indium gallium zinc oxide semiconductor layer.

According to one embodiment of the present disclosure, the flexible substrate is provided with a first flexible sub-layer, an inorganic sub-layer, and a second flexible sub-layer in sequence.

According to one embodiment of the present disclosure, the first flexible sub-layer and the second flexible sub-layer are made of polyimide.

According to one embodiment of the present disclosure, a barrier layer and a buffer layer are sequentially disposed on the flexible substrate, the barrier layer and the buffer layer are located between the flexible substrate and the driving thin film transistor and between the flexible substrate and the switching thin film transistor.

According to one embodiment of the present disclosure, the driving thin film transistor is provided with the polysilicon semiconductor layer, a first gate insulating layer, a first gate electrode layer, a second gate insulating layer, a second gate electrode layer, an interlayer dielectric layer, and a source/drain layer in sequence.

According to one embodiment of the present disclosure, the switching thin film transistor is provided with the oxide semiconductor layer, a second gate insulating layer, a second gate electrode layer, an interlayer dielectric layer, and a source/drain layer in sequence.

According to one embodiment of the present disclosure, the OLED is provided with a first electrode, an organic light emitting layer, and a second electrode in sequence, wherein the first electrode is connected to the source/drain layer of the driving thin film transistor through a conductive via, and the first electrode and the second electrode are made of a transparent conductive material.

The present disclosure further provides a thin film transistor (TFT) array substrate, including a display area, and the TFT array substrate including:

a substrate;

a driving thin film transistor disposed on the substrate and located in the display area, wherein the driving thin film transistor includes a polysilicon semiconductor layer; and

a switching thin film transistor disposed on the substrate, located in the display area, and electrically connected to the driving thin film transistor, wherein the switching thin film transistor includes an oxide semiconductor layer.

According to one embodiment of the present disclosure, the oxide semiconductor layer is an indium gallium zinc oxide (IGZO) semiconductor layer.

According to one embodiment of the present disclosure, a barrier layer and a buffer layer are sequentially disposed on the substrate, the barrier layer and the buffer layer are located between the substrate and the driving thin film transistor and between the substrate and the switching thin film transistor.

According to one embodiment of the present disclosure, the driving thin film transistor is provided with the polysilicon semiconductor layer, a first gate insulating layer, a first gate electrode layer, a second gate insulating layer, a second gate electrode layer, an interlayer dielectric layer, and a source/drain layer in sequence.

According to one embodiment of the present disclosure, the switching thin film transistor is provided with the oxide semiconductor layer, the second gate insulating layer, the second gate electrode layer, the interlayer dielectric layer, and the source/drain layer in sequence.

According to one embodiment of the present disclosure, the substrate is a flexible substrate, and the flexible substrate is provided with a first flexible sub-layer, an inorganic sub-layer, and a second flexible sub-layer in sequence.

According to one embodiment of the present disclosure, the TFT array substrate further includes a bendable area, and the TFT array substrate includes an organic filling layer disposed on the flexible substrate and located in the bendable area.

The present disclosure further provides an organic light emitting diode (OLED) panel, including:

a thin film transistor (TFT) array substrate including a display area and a bendable area, the TFT array substrate including a flexible substrate; a driving thin film transistor disposed on the flexible substrate and located in the display area, wherein the driving thin film transistor includes a polysilicon semiconductor layer; a switching thin film transistor disposed on the flexible substrate, located in the display area, and electrically connected to the driving thin film transistor, wherein the switching thin film transistor includes an oxide semiconductor layer; and an organic filling layer disposed on the flexible substrate and located in the bendable area;

a planarization layer disposed on the TFT array substrate; and

an organic light emitting device layer disposed on the planarization layer, the organic light emitting device layer including an organic light emitting diode (OLED) located in the display area, and the OLED electrically connected with the driving thin film transistor.

According to one embodiment of the present disclosure, the OLED is provided with a first electrode, an organic light emitting layer, and a second electrode in sequence, wherein the first electrode is connected to the source/drain layer of the driving thin film transistor through a conductive via.

According to one embodiment of the present disclosure, the organic light emitting device layer is further provided with a pixel definition layer, a photoresist layer, and a thin film encapsulating (TFE) layer in sequence.

### Beneficial Effect

Since the TFT formed by the oxide semiconductor layer has a very small leakage current, using the oxide semiconductor layer (such as IGZO) as the switching thin film transistor can effectively reduce the leakage current of the switching thin film transistor and improve the display quality of the OLED panel. In addition, the oxide semiconductor layer (such as IGZO) has excellent flexibility, such that the oxide semiconductor layer can be applied to the field of the flexible display. The present disclosure can reduce the leakage current to maintain the display quality, while maintaining the bendability of the OLED panel.

### DESCRIPTION OF DRAWINGS

In order to more clearly illustrate the technical solutions in the embodiments or the prior art, the following drawings, which are intended to be used in the description of the embodiments or the prior art, will be briefly described. It is obvious that the drawings and the following description are only some embodiments of the present disclosure. Those of ordinary skill in the art may, without creative efforts, derive other drawings from these drawings.

FIG. 1 is a compensation circuit diagram of an existing organic light emitting diode (OLED) panel.

FIG. 2 is a structural cross-section view of a thin film transistor (TFT) array substrate according to an embodiment of the present disclosure.

FIG. 3 is a structural cross-section view of an OLED panel according to an embodiment of the present disclosure.

### DETAILED DESCRIPTION OF PREFERRED EMBODIMENTS

In the following detailed description of the preferred embodiments, reference is made to the accompanying drawings which form a part hereof, and in which is shown by way of illustrating specific embodiments in which the disclosure may be practiced. In this regard, directional terminology, such as “top”, “bottom”, “front”, “back”, “left”, “right”, “inside”, “outside”, “side”, etc., is used with reference to the orientation of the figure(s) being described. As such, the directional terminology is used for purposes of illustration and is in no way limiting.

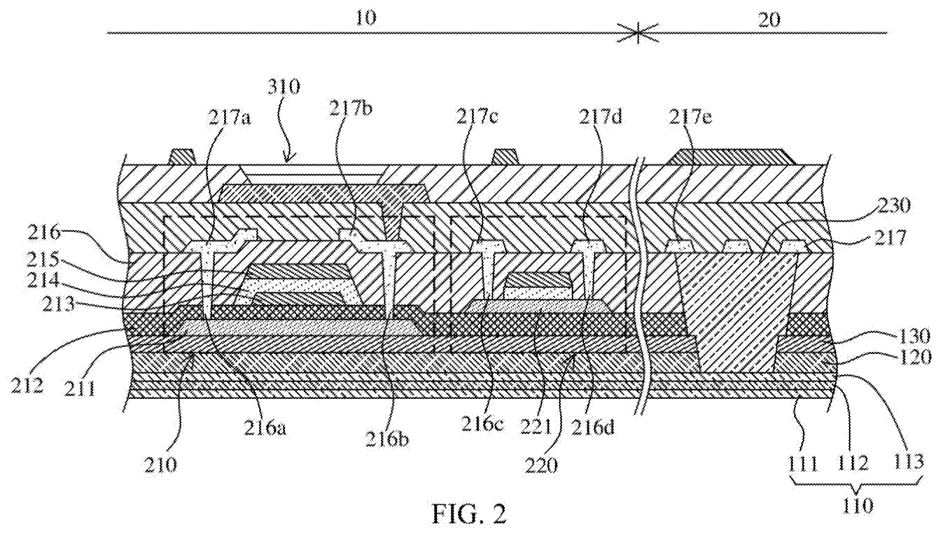

Please refer to FIG. 2. FIG. 2 is a structural cross-section view of a thin film transistor (TFT) array substrate according to an embodiment of the present disclosure. The present embodiment provides a TFT array substrate 1, the TFT array substrate 1 includes a display area 10 and a bendable area 20, and the TFT array substrate 1 includes a substrate 110, a driving thin film transistor 210, a switching thin film transistor 220, and an organic filling layer 230.

A barrier layer 120 and a buffer layer 130 are sequentially disposed on the substrate 110, the barrier layer 120 and the buffer layer 130 are located between the substrate 110 and the driving thin film transistor 210 and between the substrate 110 and the switching thin film transistor 220. The substrate 110 may be a flexible substrate, and the flexible substrate may be provided with a first flexible sub-layer, an inorganic sub-layer, and a second flexible sub-layer in sequence. The first flexible sub-layer 111 and the second flexible sub-layer 113 may be made of a flexible organic material, such as polyimide (PI) or other materials with similar characteristics. It should be understood that the flexible substrate may also be made of a single layer of the flexible organic material, such as polyimide (PI) or other materials with similar characteristics.

The driving thin film transistor 210 is disposed on the substrate 110 and located in the display area 10, wherein the driving thin film transistor 210 includes a polysilicon semiconductor layer 211, which may be used as an active region of the driving thin film transistor 210. The driving thin film transistor 210 is provided with the polysilicon semiconductor layer 211, a first gate insulating layer 212, a first gate electrode layer 213, a second gate insulating layer 214, a second gate electrode layer 215, an interlayer dielectric layer 216, and a source/drain layer 217 in sequence. Taking FIG. 2 as an example, the polysilicon semiconductor layer 211 may be defined and formed on the buffer layer 130. The first gate insulating layer 212 is defined and formed on the polysilicon semiconductor layer 211. The material of the first gate insulating layer 212 may include silicon oxide or other feasible insulating materials. The first gate electrode layer 213 is defined and formed on the first gate insulating layer 212. The first gate electrode layer 213 is made of a conductive material, such as a metal material. The second gate insulating layer 214 is defined and formed on the first gate electrode layer 213. The second gate insulating layer 214 may further cover the first gate electrode layer 213. The material of the second gate insulating layer 214 may include silicon oxide and silicon nitride, such as layered silicon oxide/silicon nitride, or other feasible materials. The second gate electrode layer 215 is defined and formed on the second gate insulating layer 214. The second gate electrode layer 215 is made of a conductive material, such as a metal material. The interlayer dielectric layer 216 is formed on the second gate electrode layer 215 and the first gate insulating layer 212. The source/drain layer 217 is defined and formed on the interlayer dielectric layer 216. The source/drain layer 217 includes a source electrode 217a of the driving thin film transistor 210 and a drain electrode 217b of the driving thin film transistor 210. The source electrode 217a and the drain electrode 217b are electrically connected to the polysilicon semiconductor layer 211 respectively through first conductive vias 216a and 216b corresponding to the source electrode 217a and the drain electrode 217b. The first conductive vias 216a and 216b penetrate the interlayer dielectric layer 216 and the first gate insulating layer 212.

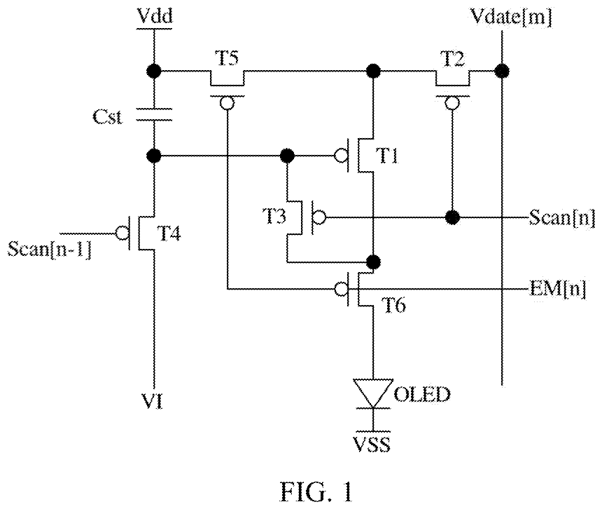

The switching thin film transistor 220 is disposed on the substrate 110, located in the display area 10, and electrically connected to the driving thin film transistor 210, as the connection between DTFT_T1 and STFT_T3 shown in FIG. 1. The switching thin film transistor 220 includes an oxide semiconductor layer 221. The oxide semiconductor layer 221 may be an indium gallium zinc oxide (IGZO) semiconductor layer or other oxide semiconductor materials having similar characteristics. The switching thin film transistor 220 is provided with the oxide semiconductor layer 221, the second gate insulating layer 214, the second gate electrode layer 215, the interlayer dielectric layer 216, and the source/drain layer 217 in sequence. When FIG. 2 is taken as an example, the oxide semiconductor layer 221 may be defined and formed on the first gate insulating layer 212, and the oxide semiconductor layer 221 may be used as an active area of the switching thin film transistor 220. The second gate insulating layer 214 is defined and formed on the first gate insulating layer 212. The material of the second gate insulating layer 214 may include silicon oxide and silicon nitride, such as layered silicon oxide/silicon nitride, or other feasible materials. The second gate electrode layer 215 is defined and formed on the second gate insulating layer 214. The second gate electrode layer 215 is made of a conductive material, such as a metal material. The interlayer dielectric layer 216 is formed on the second gate electrode layer 215 and the first gate insulating layer 212. The source/drain layer 217 is defined and formed on the interlayer dielectric layer 216. The source/drain layer 217 includes a source electrode 217c of the switching thin film transistor 220 and a drain electrode 217d of the switching thin film transistor 220. The source electrode 217c and the drain electrode 217d are electrically connected to the oxide semiconductor layer 221 respectively through second conductive vias 216c and 216d corresponding to the source electrode 217c and the drain electrode 217d. The second conductive via 216c and 216d penetrate the interlayer dielectric layer 216. That means that switching thin film transistor 220, such as STFT_T3 or STFT_T4 as shown in FIG. 1, is formed by using the oxide semiconductor layer 221 (for example, IGZO). Therefore, the display quality can be improved by reducing the leakage current of the switching thin film transistor.

The organic filling layer 230 is disposed on the substrate 110 and located in the bendable area 20. When FIG. 2 is taken as an example, a groove is provided in the bendable area 20 to receive the organic filling layer 230, thereby increasing the bendability of the TFT array substrate 1. The groove may penetrate the interlayer dielectric layer 216, the first gate insulating layer 212, the buffer layer 130, and the barrier layer 120. It should be understood that the source/drain layer 217 may also be provided on the organic filling layer 230, such as a source/drain traces 217e, and is used to electrically connect with a control chip (not shown).

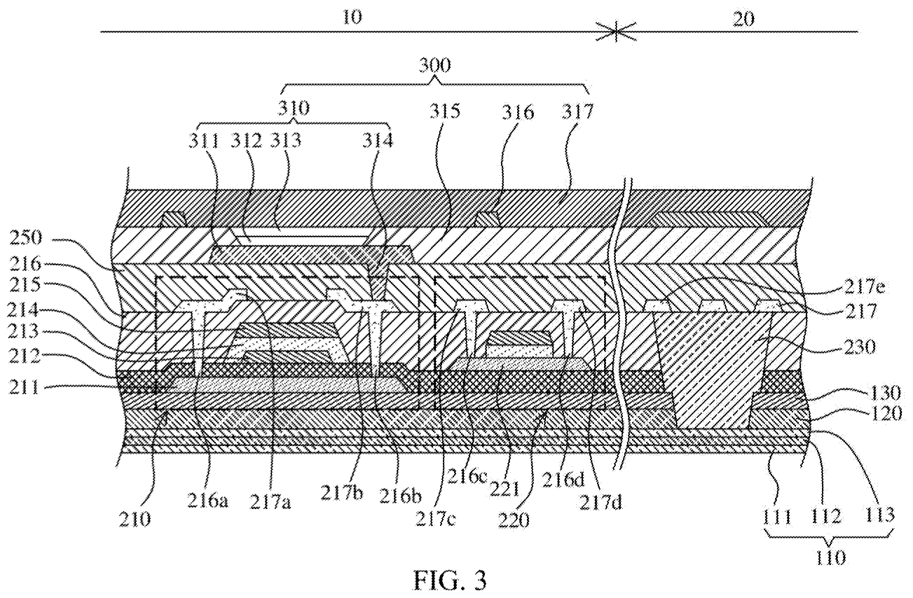

In addition, an organic light emitting diode (OLED) is further disposed in the display area 10 of the TFT array substrate 1, and the OLED 310 is electrically connected to the driving thin film transistor 210. The structure of the OLED 310 may refer to the related description of FIG. 3.

It should be understood that the term defined and formed refers to the use of deposition technology, patterning technology (such as photolithography), etching technology and other manufacturing technologies to form each film layer at a desired position in a specific pattern. It should be understood that each common film layer of the driving thin film transistor 210 and the switching thin film transistor 220 may be formed in the same process. For example, the second gate electrode layer 215 is deposited on the second gate insulating layer 214 in the same deposition process, and is formed at a desired position through a patterning technology.

Please refer to FIG. 3, FIG. 3 is a structural cross-section view of an OLED panel according to an embodiment of the present disclosure. The present embodiment provides an organic light emitting diode (OLED) panel, the OLED panel includes a thin film transistor (TFT) array substrate 1, a planarization layer 250, and an organic light emitting device layer 300.

The TFT array substrate 1 includes a display area 10 and a bendable area 20, and the TFT array substrate 1 includes a flexible substrate 110, a driving thin film transistor 210, a switching thin film transistor 220, and an organic filling layer 230.

A barrier layer 120 and a buffer layer 130 are sequentially disposed on the flexible substrate 110, the barrier layer 120 and the buffer layer 130 are located between the flexible substrate 110 and the driving thin film transistor 210 and between the flexible substrate 110 and the switching thin film transistor 220. The flexible substrate 110 is provided with a first flexible sub-layer 111, an inorganic sub-layer 112, and a second flexible sub-layer 113 in sequence. The first flexible sub-layer 111 and the second flexible sub-layer 113 may be made of a flexible organic material, such as polyimide (PI) or other materials with similar characteristics. It should be understood that the flexible substrate 110 may also be made of a single layer of the flexible organic material, such as polyimide (PI) or other materials with similar characteristics.

The driving thin film transistor 210 is disposed on the flexible substrate 110 and located in the display area 10, wherein the driving thin film transistor 210 includes a polysilicon semiconductor layer 211. The driving thin film transistor 210 is provided with the polysilicon semiconductor layer 211, a first gate insulating layer 212, a first gate electrode layer 213, a second gate insulating layer 214, a second gate electrode layer 215, an interlayer dielectric layer 216, and a source/drain layer 217 in sequence. When FIG. 3 is taken as an example, the polysilicon semiconductor layer 211 may be defined and formed on the buffer layer 130. The first gate insulating layer 212 is defined and formed on the polysilicon semiconductor layer 211. The material of the first gate insulating layer 212 may include silicon oxide or other feasible insulating materials. The first gate electrode layer 213 is defined and formed on the first gate insulating layer 212. The first gate electrode layer 213 is made of a conductive material, such as a metal material. The second gate insulating layer 214 is defined and formed on the first gate electrode layer 213. The second gate insulating layer 214 may further cover the first gate electrode layer 213. The material of the second gate insulating layer 214 may include silicon oxide and silicon nitride, such as layered silicon oxide/silicon nitride, or other feasible materials. The second gate electrode layer 215 is defined and formed on the second gate insulating layer 214. The second gate electrode layer 215 is made of a conductive material, such as a metal material. The interlayer dielectric layer 216 is formed on the second gate electrode layer 215 and the first gate insulating layer 212. The source/drain layer 217 is defined and formed on the interlayer dielectric layer 216. The source/drain layer 217 includes a source electrode 217a of the driving thin film transistor 210 and a drain electrode 217b of the driving thin film transistor 210. The source electrode 217a and the drain electrode 217b are electrically connected to the polysilicon semiconductor layer 211 respectively through first conductive vias 216a and 216b corresponding to the source electrode 217a and the drain electrode 217b. The first conductive vias 216a and 216b penetrate the interlayer dielectric layer 216 and the first gate insulating layer 212.

The switching thin film transistor 220 is disposed on the flexible substrate 110, located in the display area 10, and electrically connected to the driving thin film transistor 210. The switching thin film transistor 220 includes an oxide semiconductor layer 221. The oxide semiconductor layer 221 may be an indium gallium zinc oxide (IGZO) semiconductor layer or other oxide semiconductor materials having similar characteristics. The switching thin film transistor 220 is provided with the oxide semiconductor layer 221, the second gate insulating layer 214, the second gate electrode layer 215, the interlayer dielectric layer 216, and the source/drain layer 217 in sequence. When FIG. 3 is taken as an example, the oxide semiconductor layer 221 may be defined and formed on the first gate insulating layer 212, and the oxide semiconductor layer 221 may be used as an active area of the switching thin film transistor 220. The second gate insulating layer 214 is defined and formed on the first gate insulating layer 212. The material of the second gate insulating layer 214 may include silicon oxide and silicon nitride, such as layered silicon oxide/silicon nitride, or other feasible materials. The second gate electrode layer 215 is defined and formed on the second gate insulating layer 214. The second gate electrode layer 215 is made of a conductive material, such as a metal material. The interlayer dielectric layer 216 is formed on the second gate electrode layer 215 and the first gate insulating layer 212. The source/drain layer 217 is defined and formed on the interlayer dielectric layer 216. The source/drain layer 217 includes a source electrode 217c of the switching thin film transistor 220 and a drain electrode 217d of the switching thin film transistor 220. The source electrode 217c and the drain electrode 217d are electrically connected to the oxide semiconductor layer 221 respectively through second conductive vias 216c and 216d corresponding to the source electrode 217c and the drain electrode 217d.

The organic filling layer 230 is disposed on the flexible substrate 110 and located in the bendable area 20. When FIG. 3 is taken as an example, a groove is provided in the bendable area 20 to receive the organic filling layer 230, thereby increasing the bendability of the TFT array substrate 1. The groove may penetrate the interlayer dielectric layer 216, the first gate insulating layer 212, the buffer layer 130, and the barrier layer 120. It should be understood that the source/drain layer 217 may also be provided on the organic filling layer 230, such as a source/drain traces 217e, and is used to electrically connect with a control chip (not shown).

The planarization layer 250 is disposed on the TFT array substrate 1, and the planarization layer 250 contacts the source/drain layer 217 and the interlayer dielectric layer 216.

The organic light emitting device layer 300 is disposed on the planarization layer 250. The organic light emitting device layer 300 includes an organic light emitting diode (OLED) located in the display area, and the OLED is electrically connected with the driving thin film transistor. The OLED is provided with a first electrode 311, an organic light emitting layer 312, and a second electrode 313 in sequence, wherein the first electrode 311 is connected to the source/drain layer 217 of the driving thin film transistor 210 through a third conductive via 314. The first electrode 311 and the second electrode 312 may be made of a transparent conductive material. The organic light emitting device layer 300 is further provided with a pixel definition layer 315, a photoresist layer 316, and a thin film encapsulating (TFE) layer 317 stacked in this order.

When FIG. 3 is taken as an example, the first electrode 311 of the OLED 310 is defined and formed on the driving thin film transistor 210, wherein the first electrode 311 is connected to the source/drain layer 217 (such as 217b) of the driving thin film transistor 210 through the third conductive via 314. The pixel definition layer 315 is formed on the planarization layer 250 and the first electrode 311. The pixel definition layer 315 may include an opening exposing a part of the first electrode 311, and the opening may receive the organic light emitting layer 312. The second electrode 313 is formed on the organic light emitting layer 312. The photoresist layer 316 is defined and formed on the pixel definition layer 315. It should be understood that the pixel definition layer 315 and the photoresist layer 316 may be made of the same material. For example, the pixel definition layer 315 and the photoresist layer 316 is made of the same organic material, and is defined and formed by a halftone technology.

The beneficial effect of the present disclosure is described as follow. Since the TFT formed by the oxide semiconductor layer has a very small leakage current, using the oxide semiconductor layer (such as IGZO) as the switching thin film transistor can effectively reduce the leakage current of the switching thin film transistor and improve the display quality of the OLED panel. In addition, the oxide semiconductor layer (such as IGZO) has excellent flexibility, such that the oxide semiconductor layer can be applied to the field of the flexible display. The present disclosure can reduce the leakage current to maintain the display quality, while maintaining the bendability of the OLED panel.

In view of the above, although the present invention has been disclosed by way of preferred embodiments, the above preferred embodiments are not intended to limit the present invention, and one of ordinary skill in the art, without departing from the spirit and scope of the invention, the scope of protection of the present invention is defined by the scope of the claims.

What is claimed is:

1. An organic light emitting diode (OLED) panel, comprising:
a thin film transistor (TFT) array substrate comprising a display area and a bendable area, the TFT array substrate comprising a flexible substrate; a driving thin film transistor disposed on the flexible substrate and located in the display area, wherein the driving thin film transistor comprises a polysilicon semiconductor layer; a switching thin film transistor disposed on the flexible substrate, located in the display area, and electrically connected to the driving thin film transistor, wherein the switching thin film transistor comprises an oxide semiconductor layer; and an organic filling layer disposed on the flexible substrate and located in the bendable area;
a planarization layer disposed on the TFT array substrate; and
an organic light emitting device layer disposed on the planarization layer, the organic light emitting device layer comprising an organic light emitting diode (OLED) located in the display area, and the OLED electrically connected with the driving thin film transistor;
wherein the oxide semiconductor layer is an indium gallium zinc oxide semiconductor layer.

2. The OLED panel according to claim 1, wherein the flexible substrate is provided with a first flexible sub-layer, an inorganic sub-layer, and a second flexible sub-layer in sequence.

3. The OLED panel according to claim 2, wherein the first flexible sub-layer and the second flexible sub-layer are made of polyimide.

4. The OLED panel according to claim 3, wherein a barrier layer and a buffer layer are sequentially disposed on the flexible substrate, the barrier layer and the buffer layer are located between the flexible substrate and the driving thin film transistor and between the flexible substrate and the switching thin film transistor.

5. The OLED panel according to claim 3, wherein the driving thin film transistor is provided with the polysilicon semiconductor layer, a first gate insulating layer, a first gate electrode layer, a second gate insulating layer, a second gate electrode layer, an interlayer dielectric layer, and a source/drain layer in sequence.

6. The OLED panel according to claim 3, wherein the switching thin film transistor is provided with the oxide semiconductor layer, a second gate insulating layer, a second gate electrode layer, an interlayer dielectric layer, and a source/drain layer in sequence.

7. The OLED panel according to claim 3, wherein the OLED is provided with a first electrode, an organic light emitting layer, and a second electrode in sequence, wherein the first electrode is connected to the source/drain layer of the driving thin film transistor through a conductive via, and the first electrode and the second electrode are made of a transparent conductive material.

8. A thin film transistor (TFT) array substrate, comprising a display area, and the TFT array substrate comprising:
a substrate;
a driving thin film transistor disposed on the substrate and located in the display area, wherein the driving thin film transistor comprises a polysilicon semiconductor layer; and
a switching thin film transistor disposed on the substrate, located in the display area, and electrically connected to the driving thin film transistor, wherein the switching thin film transistor comprises an oxide semiconductor layer.

9. The TFT array substrate according to claim 8, wherein the oxide semiconductor layer is an indium gallium zinc oxide semiconductor layer.

10. The TFT array substrate according to claim 8, wherein a barrier layer and a buffer layer are sequentially disposed on the substrate, the barrier layer and the buffer layer are located between the substrate and the driving thin film transistor and between the substrate and the switching thin film transistor.

11. The TFT array substrate according to claim 10, wherein the driving thin film transistor is provided with the polysilicon semiconductor layer, a first gate insulating layer, a first gate electrode layer, a second gate insulating layer, a second gate electrode layer, an interlayer dielectric layer, and a source/drain layer in sequence.

12. The TFT array substrate according to claim 11, wherein the switching thin film transistor is provided with the oxide semiconductor layer, the second gate insulating layer, the second gate electrode layer, the interlayer dielectric layer, and the source/drain layer in sequence.

13. The TFT array substrate according to claim 8, wherein the substrate is a flexible substrate, and the flexible substrate is provided with a first flexible sub-layer, an inorganic sub-layer, and a second flexible sub-layer in sequence.

14. The TFT array substrate according to claim 13, wherein the TFT array substrate further comprises a bendable area, and the TFT array substrate comprises an organic filling layer disposed on the flexible substrate and located in the bendable area.

15. An organic light emitting diode (OLED) panel, comprising:
a thin film transistor (TFT) array substrate comprising a display area and a bendable area, the TFT array substrate comprising a flexible substrate; a driving thin film transistor disposed on the flexible substrate and located in the display area, wherein the driving thin film transistor comprises a polysilicon semiconductor layer; a switching thin film transistor disposed on the flexible substrate, located in the display area, and electrically connected to the driving thin film transistor, wherein the switching thin film transistor comprises an oxide semiconductor layer; and an organic filling layer disposed on the flexible substrate and located in the bendable area;
a planarization layer disposed on the TFT array substrate; and
an organic light emitting device layer disposed on the planarization layer, the organic light emitting device layer comprising an organic light emitting diode (OLED) located in the display area, and the OLED electrically connected with the driving thin film transistor.

16. The OLED panel according to claim 15, wherein the OLED is provided with a first electrode, an organic light emitting layer, and a second electrode in sequence, wherein the first electrode is connected to the source/drain layer of the driving thin film transistor through a conductive via.

17. The OLED panel according to claim 15, wherein the organic light emitting device layer is further provided with a pixel definition layer, a photoresist layer, and a thin film encapsulating (TFE) layer in sequence.
